(19) United States
(12) Patent Application Publication
(10) Pub. No.: US 2026/0190809 A1
(43) Pub. Date: Jul. 2, 2026

(54) DISPLAY PANEL

(71) Applicant: LG Display Co., Ltd., Seoul (KR)

(72) Inventors: Ji Eun OH, Paju-si (KR); Tae Joon SONG, Paju-si (KR)

(73) Assignee: LG Display Co., Ltd., Seoul (KR)

(21) Appl. No.: 19/403,581

(22) Filed: Nov. 28, 2025

(30) Foreign Application Priority Data
Dec. 27, 2024 (KR) 10-2024-0198916

(51) Int. Cl. H10K 59/80; G06F 3/044; H10K 59/38; H10K 59/40; H10K 102/00

(52) U.S. Cl. CPC H10K 59/879; G06F 3/0446; H10K 59/38; H10K 59/40; H10K 59/8792; H10K 2102/351

(57) ABSTRACT

A display panel includes a plurality of unit pixels disposed on an active area of a substrate, a plurality of first directional subpixels configured to emit light for a first image and a plurality of second directional subpixels configured to emit light for a second image, the first and second directional subpixels being provided in the same unit pixel, a plurality of lenses located above the first and second directional subpixels, and a plurality of light control metal layers located on the lenses and configured to control an emission direction of light emitted from the first and second directional subpixels, wherein the light control metal layers cover different portions of upper surfaces of the lenses so that the plurality of first directional subpixels emit light in a first emission direction and the plurality of second directional subpixels emit light in a second emission direction.

This application claims the benefit of Korean Patent Application No. 10-2024-0198916, filed on Dec. 27, 2024, which is hereby incorporated by reference as if fully set forth herein.

### BACKGROUND

### Field of the Disclosure

The present disclosure relates to a display panel.

### Discussion of the Related Art

As information technology develops, the market for display devices, which are a connection medium between users and information, is growing. Accordingly, display devices, such as light-emitting diode (LED) displays, quantum dot displays (QDDs), and liquid crystal displays (LCDs), are being increasingly used.

The above-described display devices include a display panel including subpixels, a driver that outputs a driving signal to drive the display panel, and a power supply that generates power to be supplied to the display panel or the driver.

The display devices may display images by allowing selected subpixels to transmit light or directly emit light when driving signals, such as scan signals and data signals, are supplied to the subpixels formed on the display panel.

Recently, the above-described display devices are installed on dashboards within vehicles. A driver in the driver's seat may check information related to driving of the vehicle through the display device, and a passenger in the front passenger seat may check information other than the driving information through the display device.

However, if the driver and the passenger use the same display device together, this case may interfere with checking the driving information.

### SUMMARY

Accordingly, the present disclosure is directed to a display panel that substantially obviates one or more problems due to limitations and disadvantages of the related art.

An object of the present disclosure is to provide a display device that is capable of outputting different images to a driver and a passenger.

Another object of the present disclosure is to provide a display device that is capable of correcting or mitigating brightness reduction of images output to a driver and a passenger, respectively.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a display panel includes a substrate including an active area and a non-active area, a plurality of unit pixels disposed on the active area of the substrate, a plurality of first directional subpixels configured to emit light for a first image and a plurality of second directional subpixels configured to emit light for a second image, the plurality of first directional subpixels and the plurality of second directional subpixels being provided in the same unit pixel among the plurality of unit pixels, a plurality of lenses located above each of the first directional subpixels and the second directional subpixels, and a plurality of light control metal layers located on the plurality of lenses and configured to control an emission direction of light emitted from the plurality of first and second directional subpixels, wherein the plurality of light control metal layers cover different portions of upper surfaces of the plurality of lenses so that the plurality of first directional subpixels emit light in a first emission direction and the plurality of second directional subpixels emit light in a second emission direction different from the first emission direction.

Each of the plurality of light control metal layers may be located to extend from one side of a bottom surface of a corresponding one of the plurality of lenses to a portion of an upper surface of the corresponding lens, and each of the plurality of lenses may have an exposed portion configured not to overlap the light control metal layers.

Exposed portions of the plurality of lenses may be located adjacent to each other.

A cover width of the plurality of light control metal layers may be greater than ⅓ of a width of the lenses and less than ⅔ of the width of the lenses.

A thickness of the plurality of light control metal layers may be smaller than a maximum thickness of the plurality of lenses, and the plurality of light control metal layers may have a curved surface having the same shape as a curved surface of the plurality of lenses.

The plurality of lenses may include first lenses located above the first directional subpixels, and second lenses located above the second directional subpixels, the plurality of light control metal layers may include first and second directional light control metal layers, the first directional light control metal layer may extend from a first side of a bottom surface of the first lens located opposite the first emission direction to a portion of an upper surface of the first lens, and the second directional light control metal layer may extend from a second side of a bottom surface of the second lens located opposite the second emission direction to a portion of an upper surface of the second lens.

At least one of the plurality of first directional subpixels and at least one of the plurality of second directional subpixels in the unit pixel may emit light having the same color.

Touch driving electrodes and touch sensing electrodes may be located to be spaced apart from each other on a bank configured to distinguish between the plurality of first directional subpixels and the plurality of second directional subpixels, some of the plurality of light control metal layers located on the plurality of lenses may function as the touch driving electrodes, and a remainder of the plurality of light control metal layers located on the plurality of lenses may function as the touch sensing electrodes.

The display panel may further include a bridge metal layer located between light-emitting elements and the plurality of lenses and configured to overlap the bank.

The display panel may further include a plurality of auxiliary metal layers configured to conductively connect the light control metal layers located on the lenses of the first and second directional subpixels adjacent to each other and overlap the bank, and some of the plurality of auxiliary metal layers may be connected to the bridge metal layer.

A first black matrix may be located on the plurality of light control metal layers.

Color filters may be located on exposed portions of the plurality of lenses configured not to overlap the plurality of light control metal layers.

The color filters may be provided as a single layer to cover upper surfaces of two lenses on the first and second directional subpixels adjacent to each other.

A second black matrix spaced apart upward from the plurality of light control metal layers may be located in areas configured to overlap the plurality of light control metal layers.

The second black matrix may overlap a portion of each of emission areas of the plurality of first and second directional subpixels.

It is to be understood that both the foregoing general description and the following detailed description of the present disclosure are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain various principles of the present disclosure. In the drawings:

FIG. 1 is a diagram illustrating an example to which a display device of the present disclosure is applied;

FIG. 2 is a diagram illustrating the concept of the configuration of the display device according to one or more example embodiments of the present disclosure;

FIG. 3A and FIG. 3B include diagrams illustrating examples of an equivalent circuit of a pixel applicable to a display panel of the present disclosure;

FIG. 4 is a diagram illustrating a first example embodiment of a cross-sectional structure applied to the display panel of the present disclosure;

FIG. 5A and FIG. 5B include plan views illustrating examples of the arrangement of subpixels of FIG. 4;

FIG. 6 is a diagram illustrating a second example embodiment of a cross-sectional structure applied to the display panel of the present disclosure;

FIG. 7A and FIG. 7B include views illustrating an example in which light control metal layers of the second example embodiment shown in FIG. 6 are used as touch electrodes;

FIG. 8 is a diagram illustrating a third example embodiment of a cross-sectional structure applied to the display panel of the present disclosure;

FIG. 9A and FIG. 9B include plan views illustrating examples of the arrangement of subpixels provided with color filters of FIG. 8; and

FIG. 10 is a diagram illustrating a fourth example embodiment of a cross-sectional structure applied to the display panel of the present disclosure.

### DETAILED DESCRIPTION

Hereinafter, example embodiments will be described with reference to the accompanying drawings.

The same reference numerals or symbols in different drawings indicate similar or identical components. In addition, some of the drawings may be exaggerated for effective explanation of the thicknesses, ratios, and dimensions of components. Components illustrated in the drawings may have a different scale from the actual scale for convenience of explanation and are not limited to the scale illustrated in the drawings.

In the following description, where a component (region, layer, part, or the like) is referred to as being “on,” “connected to,” or “coupled to” another component, it may be directly on, connected to, or coupled to the other component, or intervening components may be present.

As used herein, the term “and/or” includes any and all combinations of one or more of the associated listed items.

Terms, such as “first,” “second,” and the like, are used to describe various component, and these components should not be construed as being limited by these terms. These terms are used only to refer to one component separately from other components. For example, a first component described hereinafter may be termed a second component, and similarly, a second component described hereinafter may be termed as a first component, without departing from the scope of the disclosure. Singular expressions may encompass plural expressions, and vice versa, unless they have clearly different contextual meanings.

Terms, such as “below,” “under,” “above,” “on,” and the like, may be used to describe the relationship between components illustrated in the drawings. The terms are relative concepts and are described based on the orientation illustrated in the drawings. For example, one or more other parts may be located between two parts unless a more specific term like “directly” or “immediately” is used. Spatially relative terms, such as “below,” “beneath,” “lower,” “above,” “upper,” and the like, may be used herein for ease of description to describe a relationship between one element or component and another element or component as shown in the drawings. For example, “below” or “lower” with respect to a first component may be in the opposite direction to “above” or “upper” with respect to the first component.

It should be understood that the spatially relative terms may encompass different orientations of an element in use or operation in addition to the orientation depicted in the figures. For example, if an element in the figures is turned over, elements described as “below” or “beneath” other elements would then be oriented “above” the other elements. Thus, the example term “below” may encompass both an orientation of below and above.

The terms “comprises,” “comprising,” “including,” and “having” are inclusive and therefore specify the presence of stated features, integers, steps, operations, elements, components, and/or combinations thereof, but do not preclude the possibility the presence or addition of one or more other features, integers, steps, operations, elements, components, and/or combinations thereof.

Individual features of various embodiments in the following description may be partially or wholly coupled to or combined with each other, and may be technically interconnected and operated in various ways, and the respective embodiments may be implemented independently of each other or implemented together in a related manner.

Hereinafter, a display device of the present disclosure will be described with reference to the accompanying drawings and example embodiments.

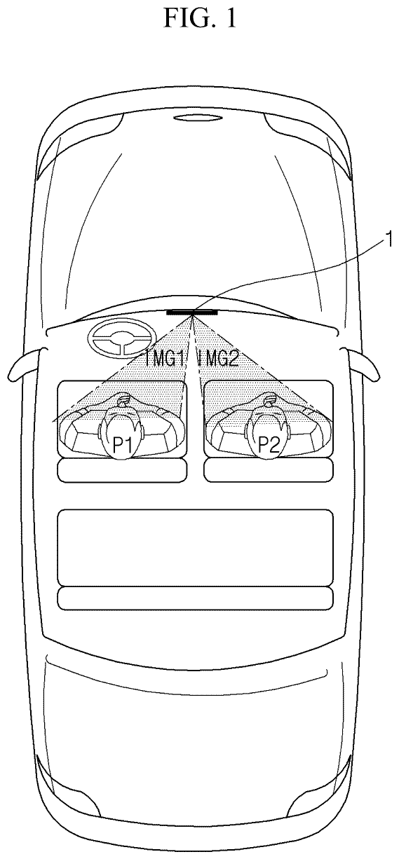

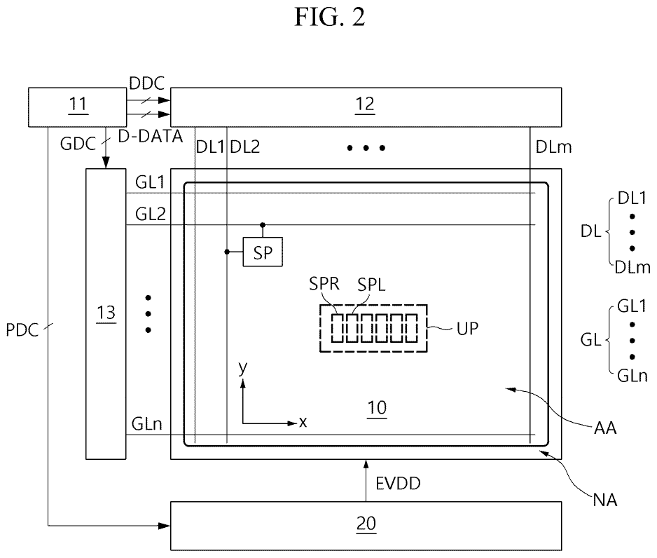

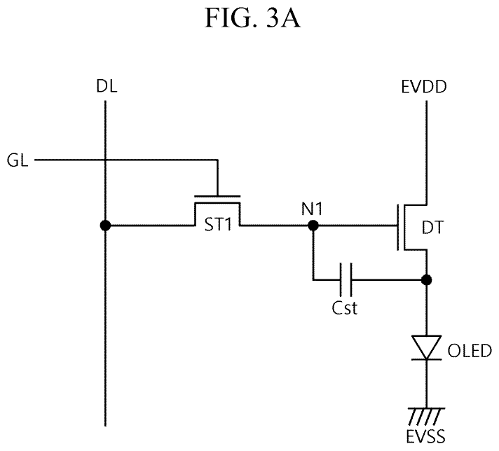

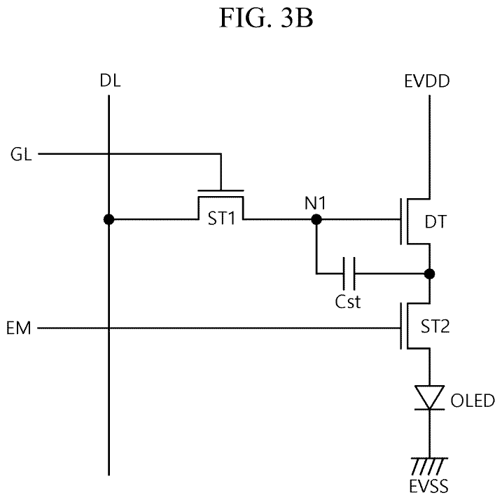

FIG. 1 is a diagram illustrating an example to which the display device of the present disclosure is applied, FIG. 2 is a diagram illustrating the concept of the configuration of the display device according to one or more example embodiments of the present disclosure, and FIG. 3A and FIG. 3B include diagrams illustrating examples of an equivalent circuit of a subpixel applicable to a display panel of the present disclosure.

As shown in FIG. 1, a display device 1 of the present disclosure may be mounted on a dashboard in a vehicle, and the display device 1 may output video images from different sources to a driver P1 seated in the driver's seat and a passenger P2 seated in the passenger seat.

For example, the display device 1 may control light emitted from subpixels provided in each unit pixel UP of the display device 1 so that a first image IMG1 related to driving information is provided to the driver P1, and a second image IMG2 for a video, such as a movie or music video, unrelated to the driving information is provided to the passenger P2.

As shown in FIG. 2, the display device 1 according to one or more example embodiments of the present disclosure may include a display panel 10, a timing controller 11, a data driver 12, a gate driver 13, and a power supply 20.

FIG. 2 illustrates a case in which the timing controller 11, the data driver 12, and the power supply 20 are provided separately as an example, but, unlike FIG. 2, the timing controller 11, the data driver 12, and the power supply 20 may be integrated in whole or in part within a drive integrated circuit. In FIG. 2, the data driver 12, the gate driver 13, and the power supply 20 may have a panel driving circuit to drive the display panel 10.

Although FIG. 2 illustrates a case in which the gate driver 13 is provided separately from the display panel 10, the present disclosure is not limited thereto, and the gate driver 13 may be provided in a non-active area NA of the display panel 10, and may be formed directly on a substrate of the display panel 10 in a Gate driver In Panel (GIP) manner.

The display panel 10 may include an active area AA and the non-active area NA.

The active area AA may be an area where an image is displayed. A plurality of subpixels SP is disposed in the active area AA, and an image may be displayed using the plurality of subpixels SP. An area where the plurality of subpixels SP is disposed may serve as the active area AA, and an area other than the active area AA may serve as the non-active area NA.

The plurality of subpixels SP disposed in the active area AA may emit light having different colors, such as red (R), green (G), and blue (B). For example, the plurality of subpixels SP may include subpixels that emit light having different colors.

The plurality of subpixels SP that emits light having different colors may be grouped into one unit pixel UP.

When defining a pixel group for color expression as a unit pixel UP, the unit pixel UP may be configured to include, for example, a plurality of subpixels that emits red (R) light, green (G) light, and blue (B) light, or may further include a subpixel that emits white (W) light in addition to red (R) light, green (G) light, and blue (B) light. Each unit pixel UP may express various colors by mixing different colors of light emitted by the plurality of subpixels SP.

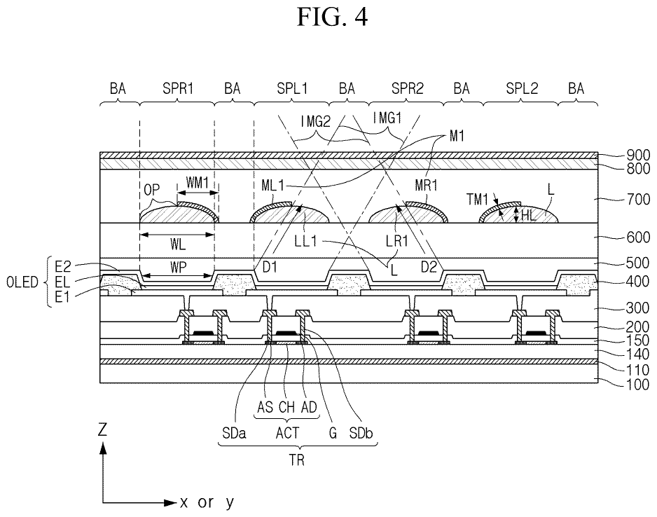

The unit pixel UP of the present disclosure may include a plurality of first directional subpixels SPL and a plurality of second directional subpixels SPR, to emit different first and second images IMG1 and IMG2 to the driver and the passenger. The first directional subpixel SPL may refer to a pixel controlled to direct light in a first emission direction (e.g., D1 in FIG. 4), and the second directional subpixel SPR may refer to a pixel controlled to direct light in a second emission direction (e.g., D2 in FIG. 4) opposite the first emission direction. For example, the first directional subpixel SPL may refer to a pixel controlled to direct light in a left direction where the driver is located, and the second directional subpixel SPR may refer to a pixel controlled to direct light in a right direction where the passenger is located.

The non-active area NA may be disposed in the edge area surrounding the active area AA that displays an image. At least one panel driving circuit for driving the plurality of subpixels SP may be disposed in the non-active area NA.

The timing controller 11 may supply digital image data D-DATA transmitted from a host system (not shown) to the data driver 12.

The timing controller 11 may receive timing signals, such as a vertical synchronization signal, a horizontal synchronization signal, a data enable signal, and a dot clock signal, from the host system and generate timing control signals for controlling the operation timing of the panel driving circuit.

The timing control signals may include a gate timing control signal GDC for controlling the operation timing of the gate driver 13, a data timing control signal DDC for controlling the operation timing of the data driver 12, and a power timing control signal PDC for controlling the operation timing of the power supply 20.

The data driver 12 may be connected to the plurality of subpixels SP through data lines DL (DL1 to DLm). The data driver 12 may generate data voltages Vdata, which are analog signals for driving the plurality of subpixels SP, based on the digital image data D-DATA input from the timing controller 11, and supply the data voltages Vdata to the data lines DL.

The data driver 12 may convert into parallel data by performing data sampling and latch based on the digital image data D-DATA and the data timing control signal DDC input from the timing controller 11, convert the digital image data D-DATA into analog data voltages Vdata depending on gamma compensation voltages in a digital-to-analog converter (hereinafter, DAC), and supply the analog data voltages Vdata to the plurality of subpixels SP through the data lines DL. The analog data voltages Vdata may be analog voltage values of different voltage levels so as to correspond to image gray levels to be expressed by the plurality of subpixels SP.

The data driver 12 may output the data voltages Vdata to the plurality of subpixels SP depending on the data timing control signal DDC. The data driver 12 may include a plurality of source driver integrated circuits. The source driver integrated circuit may include a shift register, a latch, a level shifter, a DAC, and an output buffer.

The data driver 12 may supply the data voltages of the digital image data D-DATA converted from different image sources, so that the first and second directional subpixels SPL and SPR emit light for the different first and second images IMG1 and IMG2.

The gate driver 13 may generate scan signals SC based on the gate timing control signal GDC and supply the scan signals SC to the plurality of subpixels SP through gate lines GL (GL1 to GLn), and in some cases, generate emission control signals EM1 and EM2 based on the gate timing control signal GDC and supply the emission control signals EM1 and EM2 to the plurality of subpixels SP.

The power supply 20 may process input power depending on the power timing control signal PDC to generate a high-potential driving voltage EVDD with a fixed potential and supply the high-potential driving voltage EVDD to the display panel 10.

At least one subpixel SP among the plurality of subpixels SP may include, for example, a first switching transistor ST1, a driving transistor DT, a capacitor Cst, and a light-emitting element OLED, as shown in FIG. 3A.

A first electrode (e.g., a drain electrode) of the first switching transistor ST1 may be conductively connected to the data line DL, a second electrode (e.g., a source electrode) of the first switching transistor ST1 may be conductively connected to a first node N1, and a gate electrode of the first switching transistor ST1 may be conductively connected to the gate line GL. The first switching transistor ST1 may transmit the data signal supplied through the data line DL to the first node N1 in response to the scan signal supplied through the gate line GL.

The capacitor Cst may be conductively connected to the first node N1, and charge the first node N1 with a voltage applied thereto.

A first electrode (e.g., a drain electrode) of the driving transistor DT may receive a high-potential driving voltage EVDD, and a second electrode (e.g., a source electrode) of the driving transistor DT may be conductively connected to a first electrode (e.g., an anode) of the light-emitting element OLED. The driving transistor DT may control the magnitude of a driving current flowing to the light-emitting element OLED in response to a voltage applied to a gate electrode of the driving transistor DT.

The light-emitting element OLED may output light corresponding to the driving current. The light-emitting element OLED may emit light corresponding to one color among red (R), green (G), blue (B), and white (W).

The light-emitting element OLED may include the first electrode (e.g., the anode) E1 (in FIG. 4), an emission layer EL (in FIG. 4) disposed on the first electrode E1, and a second electrode (e.g., a cathode) E2 (in FIG. 4) that supplies a common voltage.

The light-emitting element OLED may be a top emission-type diode or a bottom emission-type diode.

Although FIG. 3A illustrates a case in which the driving transistor DT is directly connected to the light-emitting element OLED as an example, the present disclosure is not limited thereto, and as shown in FIG. 3B, the driving transistor DT may be connected to the light-emitting element OLED by a second switching transistor ST2.

Specifically, as shown in FIG. 3A, the second switching transistor ST2 may be disposed between the driving transistor DT and the light-emitting element OLED, a first electrode of the second switching transistor ST2 may be connected to the driving transistor DT, and a second electrode of the second switching transistor ST2 may be conductively connected to the light-emitting element OLED. In response to an emission signal applied to the gate electrode of the driving transistor DT, the on/off of the driving current applied from the transistor DT to the light-emitting element OLED may be controlled.

In addition, although not shown in FIG. 3(a) and 3(b), a compensation circuit (not shown) for compensating for the threshold voltage of the driving transistor DT, which is a driving transistor, may be further provided within the subpixel SP. The compensation circuit may include at least one transistor connected to the driving transistor DT and be provided within the subpixel SP.

The compensation circuit may be configured in various structures, such as 3T1C including three transistors and one capacitor in the subpixel SP, 4T2C including four transistors and two capacitors, 5T2C, 6T1C, 6T2C, 7T1C, 7T2C, etc., depending on the configuration of the compensation circuit.

FIG. 4 is a diagram illustrating a first example embodiment of a cross-sectional structure applied to the display panel 10 of the present disclosure.

As shown in FIG. 4, the display panel 10 may include a substrate 100, an insulating film 110, a buffer layer 140, a gate insulating film 150, an interlayer insulating film 200, a first planarization film 300, a bank 400, the light-emitting elements OLED, a protective film 500, an optical layer 600, a plurality of lenses L, light control metal layers M1, a second planarization film 700, a polarizer 800, a cover layer 900, and transistors TR.

FIG. 4 shows a cross-section of a portion of a unit pixel UP including a plurality of first directional subpixels SPL1 and SPL2 and a plurality of second directional subpixels SPR1 and SPR2.

The plurality of first directional subpixels SPL1 and SPL2 may emit light for the first image IMG1 in the first emission direction D1, and the plurality of second directional subpixels SPR1 and SPR2 may emit light for the second image IMG2 in the second emission direction D2.

The transistor TR may be any one of the first and second switching transistors ST1 and ST2 and the driving transistor DT, and in FIG. 4, a case in which the transistor TR is the driving transistor DT shown in FIG. 3A is illustrated as an example. The cross-sectional structure of the display device of FIG. 4 is an example for understanding the present disclosure, and the present disclosure is not limited thereto.

The substrate 100 may be formed of a flexible plastic material to have flexibility, or may include a thin glass material having flexibility.

The insulating film 110 may be disposed on the active area AA and the non-active area NA on the substrate 100. The insulating film 110 may be disposed on the substrate 100 to protect structures on the substrate 100, which are vulnerable to moisture penetration, from moisture penetrating through the substrate 100. The insulating film 110 may include at least one inorganic film selected from among a silicon oxide (SiOₓ) film, a silicon nitride (SiNₓ) film, and a silicon oxynitride (SiOₓN_{y}) film.

The buffer layer 140 may be provided on the insulating film 110. The buffer layer 140 may include an inorganic insulating material, such as silicon oxide (SiOₓ) or silicon nitride (SiNₓ).

The transistors TR may be disposed on the buffer layer 140. The transistor TR may include a gate electrode G, an active layer ACT, a first or second source electrode SDa, and a first or second drain electrode SDb. The active layer ACT may include a source region AS, a channel region CH, and a drain region AD. The source region AS and the drain region AD have higher electrical conductivity than the channel region CH, and the channel region CH may form a channel in response to a voltage applied to the gate electrode G.

The gate insulating film 150 may be stacked on the buffer layer 140 while covering the active layer ACT. The gate insulating film 150 may insulate between the gate electrode G and the active layer ACT of the transistor TR.

The interlayer insulating film 200 may be located on the gate insulating film 150 to cover the gate electrode G of the transistor TR. The first or second source electrode SDa and the first or second drain electrode SDb of the transistor TR may be located on the interlayer insulating film 200.

The first or second source electrode SDa and the first or second drain electrode SDb may penetrate the interlayer insulating film 200 and the gate insulating film 150 and come into contact with the source region AS and the drain region AD of the transistor TR.

The planarization film 300 may be stacked on the interlayer insulating film 200 to cover the first or second source electrode SDa and the first or second drain electrode SDb of the transistor TR. The planarization film 300 may remove steps caused by the driving circuit, and may have a flat upper surface. The planarization film 300 may include an insulating material having high fluidity.

One of the first or second source electrode SDa and the first or second drain electrode SDb of the transistor TR may penetrate the planarization film 300 and come into contact the first electrode E1 of the light-emitting element OLED.

The bank 400 may be located on the planarization film 300. The bank 400 may include an organic insulating material. The bank 400 may cover an edge of the first electrode (e.g., the anode) E1. The emission layer EL and the second electrode (e.g., the cathode) E2 may be stacked on a portion of the first electrode E1 exposed by the bank 400. For example, the bank 400 may define an emission area of each subpixel. Bank areas BA overlapping the bank 400 may be located between the respective emission areas.

Therefore, the plurality of first directional subpixels SPL1 and SPL2 and the plurality of second directional subpixels SPR1 and SPR2 defined by the respective emission areas may be distinguished by the bank areas BA.

The light-emitting element OLED may be located in the emission area, and the light-emitting element OLED may include the first electrode E1, the emission layer EL, and the second electrode E2.

The first electrode E1 may, for example, function as an anode and include a conductive material. The first electrode E1 may have high reflectivity. For example, the first electrode E1 may include a metal, such as aluminum (Al) or silver (Ag).

The emission layer EL may generate light having a brightness corresponding to a voltage difference between the first electrode E1 and the second electrode E2. For example, the emission layer EL may include an emission material layer EML including a light-emitting material. The light-emitting material may include an organic material, an inorganic material, or a hybrid material. For example, the emission layer EL may include the emission material layer EML formed of an organic material.

The second electrode E2 functions as a cathode, for example, and may include a conductive material. The second electrode E2 may include a different material from the first electrode E1. For example, the second electrode E2 may be a transparent electrode formed of a transparent conductive material, such as ITO or IZO. The second electrode E2 may have a higher transmittance than the first electrode E1.

The protective film 500 may be disposed on the second electrode E2 on the emission layer EL and may prevent or suppress damage to the light-emitting elements OLED due to external impact and moisture. The protective film 500 may be laminated by alternately stacking inorganic insulating material layers and organic insulating material layers.

Steps caused by the light-emitting elements OLED may be removed by the protective film 500, and the upper surface of the protective film 500 may be flat.

The optical layer 600 may be disposed on the protective film 500. The optical layer 600 may form an upper surface to function as an optical gap that induces uniform light refraction by the plurality of lenses L, thereby being capable of improving light extraction efficiency. For this purpose, the optical layer 600 may have a lower refractive index than the lenses L.

The optical layer 600 may be, for example, a polymer conjugated layer (PLC) formed of various polymers, such as, an acrylic resin, a phenol resin, a polyimide resin, a polyamide resin, an unsaturated polyester resin, a polyphenylene resin, a polyphenylene sulfide resin, or benzocyclobutene.

The plurality of lenses L may be located above each of the first directional subpixels SPL1 and SPL2 and the second directional subpixels SPR1 and SPR2. In more detail, the plurality of lenses L may be disposed on the optical layer 600 and be formed of a material having a low light absorption rate. Accordingly, absorption of light emitted from the emission layer EL by the lenses L may be minimized or reduced, and the light may be easily emitted to the outside by passing through the lenses L. Accordingly, each lens L may improve the brightness of light emitted from each subpixel.

The lenses L may be formed of one of an acrylic resin, an epoxy resin, a phenol resin, a polyamide resin, a polyimide resin, an unsaturated polyester resin, a polyphenylene resin, a polyphenylene sulfide resin, benzocyclobutene, and a photoresist, but is not limited thereto. The refractive index of the lenses L may be higher than the refractive indexes of the optical layer 600 and the second planarization film 700.

The plurality of lenses L may be located above the first directional subpixels SPL1 and SPL2 and the second directional subpixels SPR1 and SPR2, and one lens L may be located above each subpixel.

The central axis of the lens L may be coincident with or different from the central axis of the light-emitting element OLED.

The light control metal layer M1 cover at least a portion of the lens L provided above each subpixel, so as to control the emission direction of the light emitted from the light emitting element OLED of each subpixel.

The light control metal layers M1 may include a metal material having high reflectivity, to block a portion of the emitted light to improve reduction in brightness. For example, the light control metal layers M1 may include a metal having high reflectivity, such as aluminum (Al) or silver (Ag). Accordingly, the light emitted from each subpixel may be controlled to be directed towards the first or second emission direction D1 or D2 by the light control metal layer M1 and the first electrode E1 of the light emitting element OLED.

The light control metal layers M1 may cover different portions of the upper surfaces of the plurality of lenses L so that first directional subpixels SPL1 and SPL2 emit light in the first emission direction D1 and the second directional subpixels SPR1 and SPR2 emit light in the second emission direction different from the first emission direction D1. The light control metal layers M1 will be described in detail after describing the basic structure of the display panel 10.

The second planarization film 700 may be located on the plurality of lenses L and remove steps caused by the plurality of lenses L. The second planarization film 700 may include a polymer material having a lower refractive index than the lenses L. If the second planarization film 700 includes a polymer material, the second planarization film 700 may include, for example, a polymer, such as an acrylic resin, a phenol resin, a polyimide resin, a polyamide resin, an unsaturated polyester resin, a polyphenylene resin, a polyphenylene sulfide resin, or benzocyclobutene. For example, the second planarization film 700 may have the same refractive index as the optical layer 600 and be formed of the same material as the optical layer 600.

The polarizer 800 may be disposed on the second planarization film 700 and reduce reflection of external light. The cover layer 900 may be disposed on the polarizer 800 and include glass formed of a light-transmitting material.

In the above-described structure of the display panel 10, the light control metal layers M1 according to the present disclosure may cover different portions of the upper surfaces of the plurality of lenses L so that the first directional subpixels SPL1 and SPL2 emit light in the first emission direction D1 and the second directional subpixels SPR1 and SPR2 emit light in the second emission direction D2.

Accordingly, the display panel 10 of the present disclosure may cause the first image IMG1 to be emitted to the driver P1 and the second image IMG2 to be emitted to the passenger P2.

The light control metal layer M1 according to the present disclosure may be located to extend from one side of the bottom surface of each lens L to a portion of the upper surface of the lens L to control the emission direction of the first and second directional subpixels SPL1, SPL2, and SPR1, SPR2, and each of the plurality of lenses L may have an exposed portion OP, which is exposed from the light control metal layer M1 so that light is emitted therethrough, among the upper surface of each lens L. The exposed portion OP may be a portion that does not overlap the light control metal layer M1.

A cover width WM1 of the light control metal layers M1 may be greater than ⅓ and less than ⅔ of a lens width WL. Here, the cover width WM1 of the light control metal layer M1 may mean the width of an image of the light control metal layer M1 projected on the bottom surface of each lens L.

The lens width WL may be, for example, between 0.8 and 1.2 times the width WP of the emission areas of the subpixels defined by the bank 400. The width WP of the emission area may be an interval between two adjacent banks 400.

A thickness TM1 of the light control metal layers M1 may be smaller than the maximum thickness HL of the lenses L, and the light control metal layers M1 may have a curved surface having the same shape as the curved surface of the lenses L. The present disclosure may minimize or reduce the thickness of the light control metal layers M1, thereby being capable of minimizing or reducing the manufacturing cost of the display panel.

The plurality of lenses L may include first lenses LL1 located above the first directional subpixels SPL1 and SPL2 and second lenses LR1 located above the second directional subpixels SPR1 and SPR2, and the light control metal layers M1 may include first and second directional light control metal layers ML1 and MR1.

The first directional light control metal layer ML1 may be located to extend from the first side of the bottom surface of the first lens LL1 to a portion of the upper surface of the first lens LL1. Here, the first side of the bottom surface of the first lens LL1 may be located opposite the first emission direction D1 of each first lens LL1. The exposed portion OP of the first lens LL1 may be located on a second side of the bottom surface of the first lens LL1.

For example, in the first directional subpixel SPL1, the first directional light control metal layer ML1 may be located to extend from the first side of the first lens LL1 to a portion of the upper surface of the first lens LL1, and the exposed portion OP of the first lens LL1 may be located at the second side of the first lens LL1, so that light from the first directional subpixel SPL1 may be controlled to be directed towards the first emission direction D1.

The second directional light control metal layer MR1 may be located to extend from the second side of the second lens LR1 to a portion of the upper surface of the second lens LR1. The second side of the bottom surface of the second lens LR1 may be located opposite the second emission direction D2. The exposed portion OP of the second lens LR1 may be located at the first side of the bottom surface of the second lens LR1.

For example, in the second directional subpixel SPR2, the second directional light control metal layer MR1 may be located to extend from the second side of the bottom surface of the second lens LR1 to a portion of the upper surface of the second lens LR1, and the exposed portion OP of the second lens LR1 may be located at the first side of the bottom surface of the second lens LR1, so that light from the second directional subpixel SPR2 may be controlled to be directed towards the second emission direction D2.

The first and second directional light control metal layers M1 on the plurality of first and second lenses L may be located adjacent to each other, and the exposed portions OP of the lenses L exposed outward from the first and second directional light control metal layers M1 on the plurality of first and second lenses L may be located adjacent to each other.

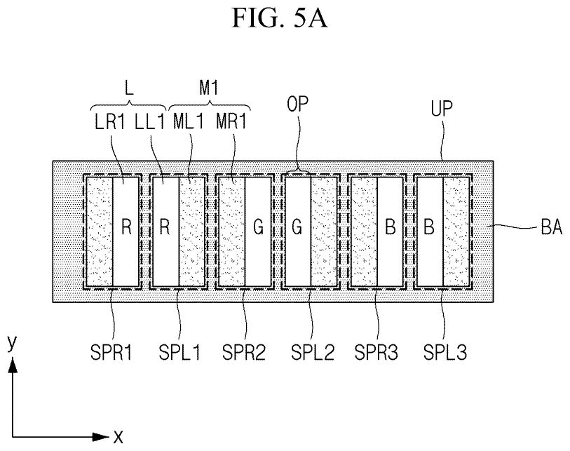

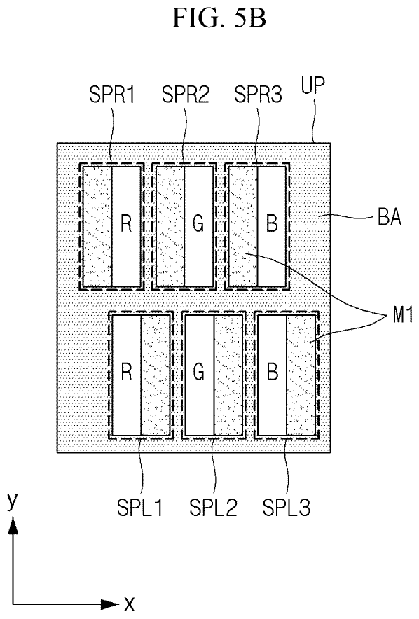

FIG. 5A and FIG. 5B include plan views illustrating examples of the arrangement of the subpixels of FIG. 4 in the unit pixel UP.

FIGS. 5A and 5B show examples of a case in which the subpixels are arranged in each unit pixel UP on the display panel 10.

One unit pixel UP according to the present disclosure may include a plurality of first and second directional subpixels SPL1, SPL2, SPL3, SPR1, SPR2, and SPR3. For example, as shown in FIG. 5A, the plurality of first and second directional subpixels SPL1, SPL2, SPL3, SPR1, SPR2, and SPR3 provided in one unit pixel UP may be arranged in the same row.

In an example embodiment of the present disclosure, to display different first and second images IMG1 and IMG2 within the same unit pixel UP, at least one of the plurality of first directional subpixels SPL1, SPL2, and SPL3 and at least one of the plurality of second directional subpixels SPR1, SPR2, and SPR3 included in the same unit pixel UP may emit light having the same color.

For example, the plurality of first directional subpixels SPL1, SPL2, and SPL3 and the plurality of second directional subpixels SPR1, SPR2, and SPR3 may be arranged in the same row. The plurality of first directional subpixels SPL1, SPL2, and SPL3 may include subpixels that display colors R, G, and B to display the first image IMG1, and the plurality of second directional subpixels SPR1, SPR2, and SPR3 may include subpixels that display colors R, G, and B to display the second image IMG2.

In FIG. 5A, a case in which the first and second directional subpixels SPL1 and SPR1, SPL2 and SPR2, or SPL3 and SPR3, which display the same color, are located adjacent to each other is illustrated as an example, but the present disclosure is not limited thereto.

In addition, as another example, as shown in FIG. 5B, a plurality of first directional subpixels SPL1, SPL2, and SPL3 and a plurality of second directional subpixels SPR1, SPR2, and SPR3 provided in one unit pixel UP may be arranged in different rows.

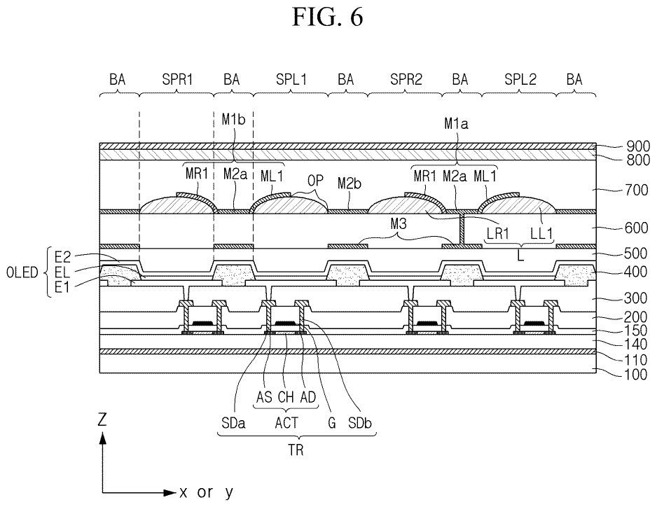

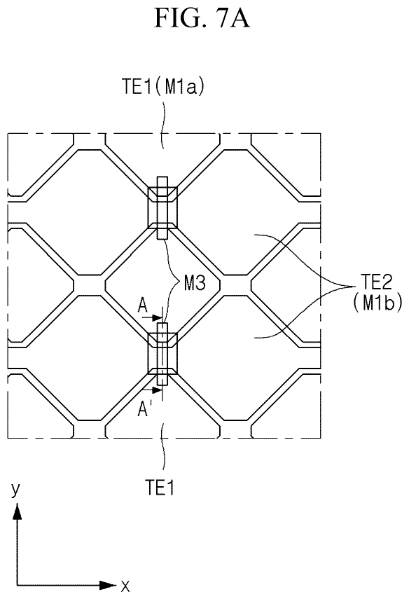

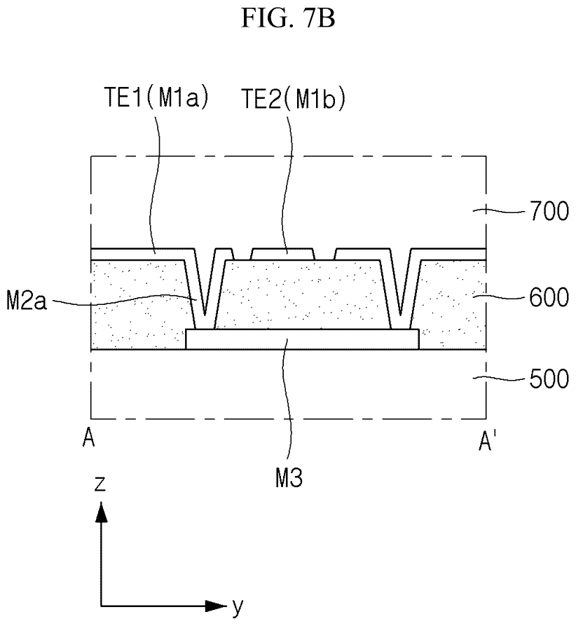

The first and second directional light control metal layers ML1 and MR1 of the present disclosure may be used as touch electrodes. This will be described with reference to FIGS. 6, 7A and 7B.

FIG. 6 is a diagram illustrating a second example embodiment of a cross-sectional structure applied to the display panel 10 of the present disclosure, and FIG. 7A and FIG. 7B includes views illustrating touch driving electrodes and touch sensing electrodes.

The first and second light control metal layers ML1 and MR1 of the present disclosure according to the second embodiment may be used as touch electrodes.

For the first and second light control metal layers ML1 and MR1 to be used as touch electrodes, the present disclosure according to the second embodiment may further provide a plurality of auxiliary metal layers M2a and M2b on the optical layer 600 between the first and second lenses LL1 and LR1. The plurality of auxiliary metal layers M2a and M2b may overlap the bank 400.

The plurality of auxiliary metal layers M2a and M2b may include first and second auxiliary metal layers M2a and M2b. The first auxiliary metal layer M2a may be located between the first and second optical control metal layers ML1 and MR1 adjacent to each other, and the second auxiliary metal layer M2b may be located between the exposed portions OP of the first and second lenses LL1 and LR1 on which the first and second optical control metal layers ML1 and MR1 are not located.

The first auxiliary metal layer M2a may conductively connect the first and second optical control metal layers ML1 and MR1 adjacent to each other.

For example, the first and second optical control metal layers ML1 and MR1 located on the first directional subpixel SPL2 and the second directional subpixel SPR2 among the plurality of first and second optical subpixels may be conductively connected to each other through the first auxiliary metal layer M2a. The first light control metal layer ML1 and the second light control metal layer MR1 that are connected by the auxiliary metal layer M2 between the first directional subpixel SPL2 and the second directional subpixel SPR2, i.e., some light control metal layers M1a, may form first touch electrodes TE1 (in FIGS. 7A and 7B).

In addition, the first and second light control metal layers ML1 and MR1 located in the first directional subpixel SPL1 and the second directional subpixel SPR1 may be conductively connected to each other through the first auxiliary metal layer M2a. The first light control metal layer ML1 and the second light control metal layer MR1 that are connected by the auxiliary metal layer M2 between the first directional subpixel SPL1 and the second directional subpixel SPR1, i.e., the remaining light control metal layers M1b, may form second touch electrodes TE2 (in FIGS. 7A and 7B). Here, some light control metal layers M1a and the remaining light control metal layers M1b may be conductively separated from each other.

Although not illustrated, the second auxiliary metal layer M2b may be conductively connected to either one of some light control metal layers M1a and the remaining light control metal layers M1b as needed.

In addition, the present disclosure according to the second embodiment may further include a bridge metal layer M3. For example, the bridge metal layer M3 may be located between the light-emitting elements OLED and the lenses L. For example, the bridge metal layer M3 may be located between the optical layer 600 and the protective film 500, and may overlap the bank 400 and the auxiliary metal layers M2a and M2b.

Some of the plurality of auxiliary metal layers M2a and M2b may be connected to some parts of the bridge metal layer M3. For example, among the plurality of auxiliary metal layers M2a and M2b, the first auxiliary metal layer M2a located between the first directional subpixel SPL2 and the second directional subpixel SPR2 may be connected to the bridge metal layer M3 located therebelow.

The touch electrodes TE1 and TE2 may be configured as shown in FIGS. 7A) and 7B. FIG. 7A is an example of a planar configuration of the touch electrodes, and FIG. 7B is a cross-sectional view taken along line A-A′ of FIG. 7A.

As shown in FIG. 7A, the touch electrodes TE1 and TE2 may include a plurality of first touch electrodes TE1 and a plurality of second touch electrodes TE2. The plurality of first touch electrodes TE1 may serve as touch driving electrodes that transmit touch driving signals, and the plurality of second touch electrodes TE2 may serve as sensing electrodes that receive the touch driving signals.

The first touch electrode TE1 of FIGS. 7A and 7B may include some light control metal layers M1a of FIG. 6, and the second touch electrode TE2 of FIGS. 7A and 7B may include the remaining light control metal layers M1b of FIG. 6.

The plurality of first and second touch electrodes TE1 and TE2 may be arranged in a matrix, and for example, the plurality of first touch electrodes TE1 may be interconnected in the y-axis direction, and the plurality of second touch electrodes TE2 may be interconnected in the x-axis direction.

As the first and second touch electrodes TE1 and TE2 are arranged to cross each other, any one of the first and second touch electrodes TE1 and TE2 may be spaced apart from each other at the intersection (e.g., A-A′). FIG. 7A illustrates a case in which the first touch electrodes TE1 are spaced apart from each other at the intersection and the second touch electrodes TE2 extend in the x-axis direction as an example.

In this case, the first touch electrodes TE1 spaced apart from each other at the intersection (e.g., A-A′) may be conductively connected to each other through the bridge electrode layer M3 located below the second touch electrode TE2, as shown in FIG. 7B.

In this way, the first and second light control metal layers ML1 and MR1 of the present disclosure according to the second embodiment may be used as touch electrodes.

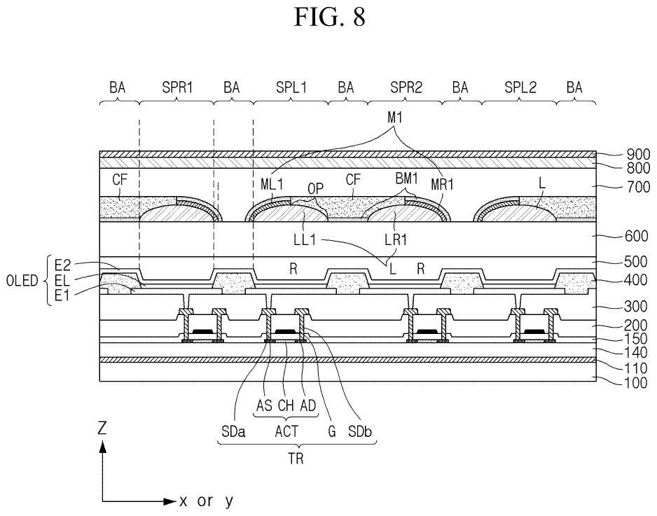

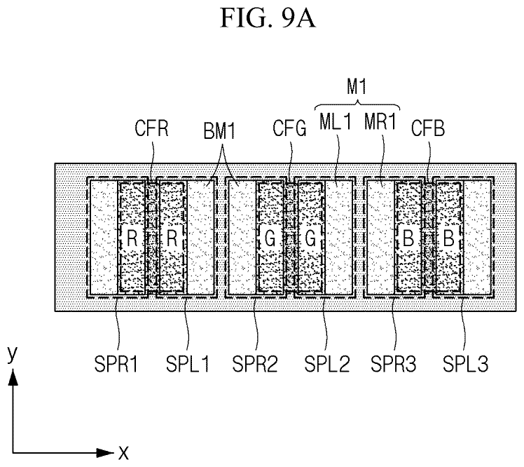

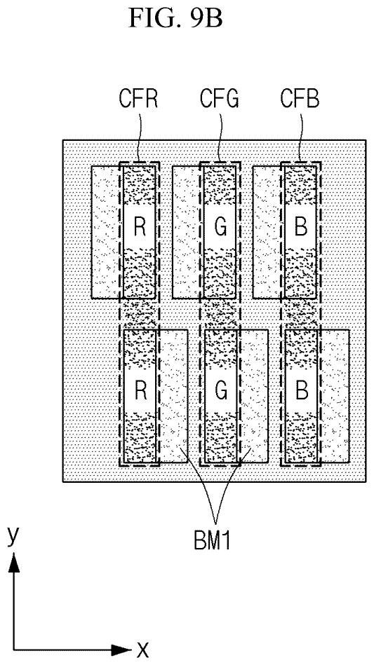

FIG. 8 is a diagram illustrating a third example embodiment of a cross-sectional structure applied to the display panel 10 of the present disclosure, and FIG. 9A and FIG. 9B include plan views illustrating examples of the arrangement of subpixels provided with color filters CF of FIG. 8.

As shown in FIG. 8, in the third example embodiment of the present disclosure, the display panel may further include a first black matrix BM1 and color filters CF.

The first black matrix BM1 may be located on the light control metal layers M1. The first black matrix BM1 is located on the light control metal layers M1 to prevent or suppress external light from being reflected by the light control metal layers M1, thereby reducing the reflectivity of the display panel 10. For example, as shown in FIG. 8, the first black matrix BM1 may be located between the light control metal layers M1 and the second planarization film 700, and in this case, the width of the first black matrix BM1 may be the same as the width of the light control metal layers M1.

In addition, the first black matrix BM1 may be further located between the exposed portions OP of the first lenses LL1 and the exposed portions OP of the second lenses LR1.

The color filters CF is located on the exposed portion OP exposed outward from the first black matrix BM1 in each lens L, thereby making the color of light emitted by the subpixel more vivid.

Such a color filter CF may be provided as a single layer on the upper surfaces of two adjacent lenses LL1 and LR1. That is, the first and second directional subpixels (e.g., SPL1 and SPR2) whose exposed portions OP of the two lenses LL1 and LR1 are adjacent to each other may emit light having the same color (e.g., R), and the color filter CF located on the upper surfaces of the exposed portions OP of the two lenses LL1 and LR1 may have the same color (e.g., R) as the color (e.g., R) of the respective subpixels (e.g., SPL1 and SPR2). That is, the first and second directional subpixels adjacent to each other may share one color filter CF having the same color.

Specifically, as shown in FIG. 9A, when a plurality of first and second directional subpixels SPL1, SPL2, SPL3, SPR1, SPR2, and SPR3 are arranged in a row, for example, the plurality of first directional subpixels SPL1, SPL2, and SPL3 and the plurality of second directional subpixels SPR1, SPR2, and SPR3 may be arranged so that each of the plurality of first directional subpixels SPL1, SPL2, and SPL3 and a corresponding one of the plurality of second directional subpixels SPR1, SPR2, and SPR3, i.e., the first and second directional subpixels SPL1 and SPR1, SPL2 and SPR2, or SPL3 and SPR3, may display the same color, (e.g., in order of R, G, and B).

The exposed portions OP of the lenses L in the first and second directional subpixels (e.g., SPL1 and SPR1), which emit light having the same color (e.g., R) and located are adjacent to each other, are adjacent to each other, and one color filer CFR, CFG, and CFB may be provided on the exposed portions OP of the lenses L, and have the same color as the color of the light emitted by the first and second directional subpixels SPL1 and SPR1.

As shown in FIG. 9B, even when a plurality of first directional subpixels SPL1, SPL2, and SPL3 and a plurality of second directional subpixels SPR1, SPR2, and SPR3 are arranged in different rows, the first and second directional subpixels may share one color filter CFR, CFG, or CFB in the same manner as in FIG. 9A.

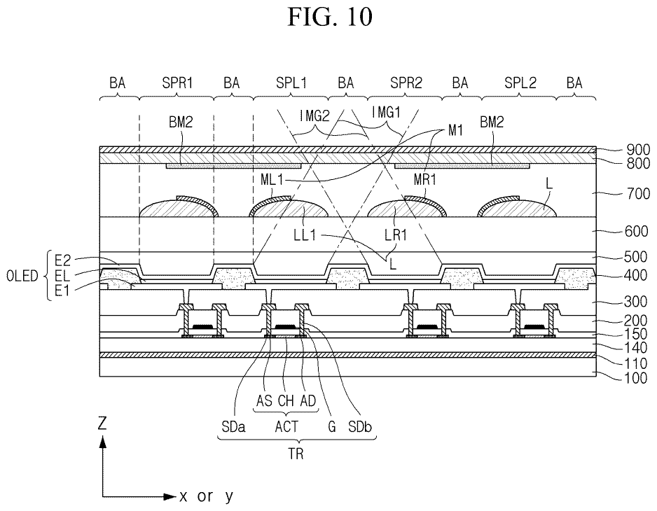

FIG. 10 is a diagram for explaining a fourth example embodiment of a cross-sectional structure applied to a display panel 10 of the present disclosure.

In the fourth example embodiment of the present disclosure, the display panel 10 may further include a second black matrix BM2 spaced apart upward from the light control metal layers M1.

As shown in FIG. 10, the second black matrix BM2 may be located spaced apart upward from the light control metal layers M1 and be located between the second planarization film 700 and the polarizer 800. The second black matrix BM2 may overlap the light control metal layer M1 located on each subpixel.

The second black matrix BM2 may overlap a portion of each of the emission areas of the first and second directional subpixels to more precisely control the direction of light emission.

In this way, one or more example embodiments of the present disclosure may provide the lens L located above each subpixel, and the light control metal layer M1 that covers at least a portion of the lens L to control the direction of light emission and have reflectivity, thereby allowing different images to be output to the driver and the passenger, and improving brightness reduction of the images by collecting light emitted from each subpixel through the light control metal layer M1 and the lens L.

As is apparent from the above description, one or more example embodiment of the present may provide a lens located above each subpixel, and a light control metal layer that covers at least a portion of the lens to control the direction of light emission and have reflectivity, thereby allowing different images to be output to a driver and a passenger, while improving brightness reduced by the light control metal layer through reflected light by the light control metal layer and light collected by the lens.

Through the above description, it should be apparent to those skilled in the art that various changes and modifications are possible without departing from the technical spirit of the present disclosure. Therefore, the technical scope of the present disclosure should not be limited to the above detailed description.

What is claimed is:

1. A display panel, comprising:
a substrate comprising an active area and a non-active area;
a plurality of unit pixels disposed on the active area of the substrate;
a plurality of first directional subpixels configured to emit light for a first image and a plurality of second directional subpixels configured to emit light for a second image, the plurality of first directional subpixels and the plurality of second directional subpixels being provided in the same unit pixel among the plurality of unit pixels;
a plurality of lenses located above each of the first directional subpixels and the second directional subpixels; and
a plurality of light control metal layers located on the plurality of lenses and configured to control an emission direction of light emitted from the plurality of first and second directional subpixels,
wherein the plurality of light control metal layers cover different portions of upper surfaces of the plurality of lenses so that the plurality of first directional subpixels emit light in a first emission direction and the plurality of second directional subpixels emit light in a second emission direction different from the first emission direction.

2. The display panel according to claim 1, wherein:
each of the plurality of light control metal layers is located to extend from one side of a bottom surface of a corresponding lens of the plurality of lenses to a portion of an upper surface of the corresponding lens; and
each of the plurality of lenses has an exposed portion configured not to overlap the light control metal layers.

3. The display panel according to claim 1, wherein exposed portions of the plurality of lenses are located adjacent to each other.

4. The display panel according to claim 1, wherein a cover width of the plurality of light control metal layers is greater than ⅓ of a width of the lenses and less than ⅔ of the width of the lenses.

5. The display panel according to claim 1, wherein a thickness of the plurality of light control metal layers is smaller than a maximum thickness of the plurality of lenses, and the plurality of light control metal layers have a curved surface having the same shape as a curved surface of the plurality of lenses.

6. The display panel according to claim 1, wherein:
the plurality of lenses comprise first lenses located above the plurality of first directional subpixels and second lenses located above the plurality of second directional subpixels;
the plurality of light control metal layers comprise first and second directional light control metal layers;
the first directional light control metal layer extends from a first side of a bottom surface of the first lens located opposite the first emission direction to a portion of an upper surface of the first lens; and
the second directional light control metal layer extends from a second side of a bottom surface of the second lens located opposite the second emission direction to a portion of an upper surface of the second lens.

7. The display panel according to claim 1, wherein at least one of the plurality of first directional subpixels and at least one of the plurality of second directional subpixels in the unit pixel emit light having the same color.

8. The display panel according to claim 1, wherein:
touch driving electrodes and touch sensing electrodes are located to be spaced apart from each other on a bank configured to distinguish between the plurality of first directional subpixels and the plurality of second directional subpixels;
some of the plurality of light control metal layers located on the plurality of lenses function as the touch driving electrodes; and
a remainder of the plurality of light control metal layers located on the plurality of lenses function as the touch sensing electrodes.

9. The display panel according to claim 8, further comprising a bridge metal layer located between light-emitting elements and the plurality of lenses and configured to overlap the bank.

10. The display panel according to claim 9, further comprising a plurality of auxiliary metal layers configured to conductively connect the light control metal layers located on the lenses of the first and second directional subpixels adjacent to each other and overlap the bank,
wherein some of the plurality of auxiliary metal layers are connected to the bridge metal layer.

11. The display panel according to claim 1, wherein a first black matrix is located on the plurality of light control metal layers.

12. The display panel according to claim 1, wherein color filters are located on exposed portions of the plurality of lenses configured not to overlap the plurality of light control metal layers.

13. The display panel according to claim 12, wherein the color filters are provided as a single layer to cover upper surfaces of two lenses on the first and second directional subpixels adjacent to each other.

14. The display panel according to claim 1, wherein a second black matrix spaced apart upward from the plurality of light control metal layers is located in areas configured to overlap the plurality of light control metal layers.

15. The display panel according to claim 14, wherein the second black matrix overlaps a portion of each of emission areas of the plurality of first and second directional subpixels.
